(19) United States
(12) Patent Application Publication
(10) Pub. No.: US 2011/0149667 A1
(43) Pub. Date: Jun. 23, 2011

(54) REDUCED AREA MEMORY ARRAY BY USING SENSE AMPLIFIER AS WRITE DRIVER

(76) Inventors: Fatih Hamzaoglu, Portland, OR (US); Kevin Zhang, Portland, OR (US)

(21) Appl. No.: 12/645,645

(22) Filed: Dec. 23, 2009

(51) Int. Cl. G11C 7/00; G11C 8/10

(52) U.S. Cl. 365/203; 365/205; 365/230.06

(57) ABSTRACT

Techniques are disclosed for reducing area needed for implementing a memory array, such as SRAM arrays. The techniques may be embodied, for example, in a memory array design that includes a sense amplifier configured to operate in a reading mode for readout of memory cells and a writing mode for writing to memory cells. In addition, a common column multiplexer can be used for both read and write functions (as opposed to having separate multiplexers for reading and writing).

### FIELD OF THE DISCLOSURE

The present disclosure relates to integrated circuit memory devices, and more particularly, to area reduction techniques for memory arrays.

### BACKGROUND

As is known, semiconductor memories such as static random access memory (SRAM) are commonly organized in arrays of rows and columns. In general, the intersection of a row and column results in a storage element or so-called bitcell. Each bitcell is capable of storing a binary bit of data. To write data to, and to read data from, a row or column of cells, an address is assigned to each row or column of cells. Access to the address is provided in a binary-coded address presented as input to address decoders that select a row or column for a write or read operation.

A typical SRAM bitcell consists of six to ten transistors. Each bitcell usually has one word line and two bitlines for accessing the bitcell. Input/output (I/O) circuitry of the SRAM allows read/write access to the bitcells, and generally includes read and write column multiplexers, bitline prechargers, sense amplifiers, and write drivers. The read and write column multiplexers allow sharing of a sense amplifier and write driver, respectively, by multiple columns of bitcells. The bitline prechargers are for precharging the bitlines of the memory array. During read access, the sense amplifiers detect signal difference between the two bitlines attached to the same bitcell to distinguish between logic high and low states. During write access, the write driver sends the desired logic state into the bitcell, thereby allowing either a logic 0 or a logic 1 to be written to that cell.

### BRIEF DESCRIPTION OF THE DRAWINGS

FIG. 1 is a block diagram of an example memory array configured with reduced area in accordance with an embodiment of the present invention.

FIG. 2a is a schematic diagram showing an example memory array having I/O circuitry configured with a sense amplifier for read operations, a write driver for write operations, and separate column muxes for read and write operations.

FIG. 2b shows the signal timing of the example memory array of FIG. 2a during Write-Read-Write case.

FIG. 3a is a schematic diagram showing an example memory array having I/O circuitry configured with a sense amplifier for sensing during read operations and for writing during write operations, and a column mux for both read and write operations, in accordance with an embodiment of the present invention.

FIG. 3b shows the signal timing of the example memory array of FIG. 3a during Write-Read-Write case.

FIG. 4 illustrates a system having one or more memory arrays configured in accordance with an embodiment of the present invention.

### DETAILED DESCRIPTION

Techniques are disclosed for reducing area needed for implementing a memory array, such as SRAM arrays. The techniques can be embodied, for example, in an SRAM array or sub-array to eliminate the write drivers and reduce the number of duplicate column multiplexers, thereby improving area efficiency of the array.

General Overview

As previously explained, the I/O circuitry of certain memory types, such as SRAM arrays, includes read/write column multiplexers, bitline prechargers, sense amplifiers, and write drivers. In short, this I/O circuitry occupies a significant amount of space, and effectively limits how small an array can be. This problem is exacerbated when the array is comprised of a plurality of sub-arrays, each sub-array having dedicated I/O circuitry or at least a portion of I/O circuitry.

Thus, and in accordance with an embodiment of the present invention, a memory array design is provided that allows a sense amplifier of the I/O circuitry to be used as write driver, thereby allowing for elimination of write driver circuitry. In addition, separate write and read column multiplexers are no longer needed. Rather, a single multiplexer can be used for both read and write functions. For instance, either the read or the write multiplexer can be used, allowing the other one to be eliminated. In one such case, the write multiplexers are kept and the read multiplexers are eliminated.

The techniques can be embodied, for example, in discrete memory devices (e.g., SRAM chips), integrated system designs (e.g., purpose-built silicon), or on-chip memory (e.g., microprocessor with on-chip cache). Memory types other than SRAM can equally benefit from the techniques provided herein, as will be appreciated in light of this disclosure. For instance, any memory array design having I/O circuitry that includes separate write driver and sense amplifier componentry can be can be configured in accordance with an embodiment of the present invention.

Memory Array

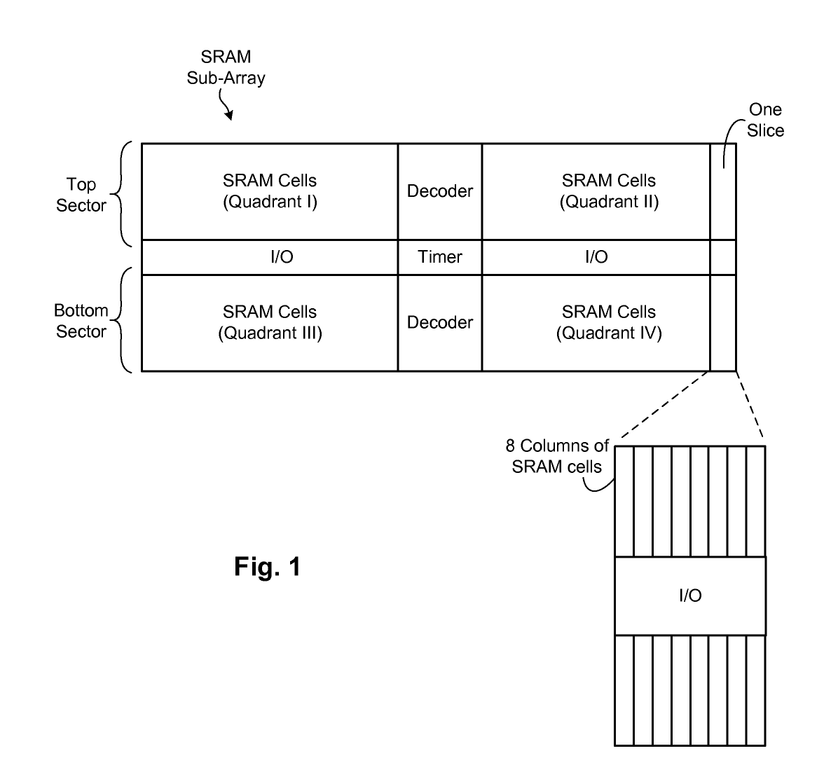

FIG. 1 is a block diagram of an example memory array configured with reduced area in accordance with an embodiment of the present invention.

As can be seen, this example embodiment is actually a sub-array that can be repeated a number of times to make up an overall memory array. For example, the overall memory array can be a 1 Mbyte cache (or other on-chip memory of a processor) that includes 64 16 Kbyte sub-arrays configured as shown. Any number of suitable array and sub-array sizes can be used, depending on particulars of the application at hand. Further note that the overall array may be a single sub-array.

The physical layout of the sub-array can vary as well, as will be appreciated. In this example embodiment, each sub-array is effectively divided into top and bottom sectors. Each sector includes two quadrants of SRAM cells, wherein the top sector includes quadrants I and II and the bottom sector includes quadrants III and IV. The SRAM cells are configured in slices/columns. As can be further seen, each slice of this example configuration includes eight columns of SRAM cells. The number of slices per quadrant can vary, and in one example configuration is between 8 and 18 slices per quadrant. Similarly, the number of SRAM cells per column of one quadrant can vary, and in one example embodiment is between 64 up to 512. In one specific case, there are 16 slices per quadrant, and 256 SRAM cells per column of one quadrant.

At the center of each slice is the I/O circuitry, which includes column multiplexers, bitline prechargers, and sense amplifiers. Note that no discrete write drivers are included in the I/O circuitry of the sub-array; rather, the sense amplifiers are used to carry out write driver functionality, as will be described in turn. Further note that there are no separate read and write column multiplexers; rather, there is one column multiplexer (per slice, in this example layout configuration) that is used for both reads and writes. At the center of the sub-array are decoders and a timer.

Numerous memory cell types and array layout architectures can be used here, as will be apparent in light of this disclosure, and the claimed invention is not intended to be limited to any particular one. Other memory array layouts may have, for example, a single array of memory cells, with a single decoder and I/O circuitry that services the entire array (instead of a quadrant-based layout having top and bottom sectors). The memory array type can be, for instance, SRAM or Flash memory, and may be volatile, non-volatile, and erasable/reprogrammable, depending on the target application and desired performance (e.g., read/write speed, reading v. writing balance such as the case where reading occurs 80% of the time and writing only 20% of the time, etc).

In general, each SRAM cell is capable of storing one bit of information, and is either set to a logic high or logic low state. Each SRAM cell can be implemented as conventionally done, using any number of typical SRAM configurations. For example, the SRAM cells may be configured as 6-T, 8-T, 10-T SRAM cells, or with any number of transistors desired per bit. Likewise, the SRAM cells can be configured with a single R/W port, or with separate read and write ports. In other embodiments, note that the memory cell may be configured with other memory cell technology, such as flash (e.g., NAND or NOR flash), or other memory cells that are accessed by separate sense amplifier (for readout of memory cells) and write driver (for writing to memory cells), and/or use separate column multiplexer circuits for write and read operations.

In this example array layout configuration, the decoders are sandwiched between quadrants of SRAM cells, and include the final decoder and word line driver, which can be implemented as conventionally done. There is a decoder for the top sector, and one for the bottom sector of the sub-array. For each read or write access, an address is provided to the sub-array. In general, the decoders are configured to decode the address, and to turn on the selected SRAM entry (or row) during each read or write access of the memory array. In one specific configuration, the address is decoded by the corresponding decoder into an address word line signal and a column select signal. The address word line signal identifies a particular row in the sub-array, and the column select signal identifies a particular column of the sub-array. The column multiplexer (of the I/O circuitry) receives the column select signal and turns on the corresponding column for read or write. Rows and columns not relevant to the read/write access operation are effectively deselected by the decoders.

The timer includes circuitry for generating the various clock signals for sub-array to be functional, including the precharge clock/control signals. The timer can be implemented as typically done, using any number of suitable timer configurations. As will be appreciated, the timer configuration will vary from one array to the next, as it is designed specifically based on the timing specification of a particular array. In general, the timer typically includes logic gates to derive the array clocks from global clock(s), and ensure the timing relationship between those different array clocks to make the sub-arrays function properly. In some embodiments, the timer may include bitline floating circuitry to enable power conservation, by allowing for floating of bitlines to eliminate or otherwise reduce power leakage associated with precharging bitlines. Other power conservation techniques can be used as well (e.g., sleep mode for I/O circuitry when array is not being accessed, or shut-off mode when the sub-array is permanently disabled for yield recovery).

The column multiplexers (or muxes) can be used to improve the array efficiency by allowing multiple columns of memory cells to share a sense amplifier. There may be, for example, a column mux for each slice (8 columns), thereby providing an 8:1 (columns:mux) sharing ratio. Other configurations may have a single column mux for the entire array. In any such cases, during each read or write access, the column mux will turn on the selected column for read or write, and deselect the other columns associated with that mux. In other embodiments having no column mux or muxes, there can be a dedicated sense amplifier for each column of the array.

The bitline prechargers are for precharging the local bitlines of the memory array, for example, to Vcc (or other suitable voltage level) when there is no read or write access. They are commonly implemented with p-type metal oxide semiconductor field effect transistors (PMOS FETs). During each read operation, the target bitline is discharging when a logic 0 is being read from the bitline, or staying at Vcc when a logic 1 is being read from the bitline. Because of loading of the local bitline, the bitline may discharge slowly. During a conventional read operation, a sense amplifier can be used to detect the small signal difference between two bitlines attached to the same SRAM cell, thereby distinguishing between a logic high or logic low states. During a conventional write operation, a write driver is used to send the desired logic state into the SRAM cell, thereby allowing either a logic 0 or a logic 1 to be written to that cell. However, recall that in this example embodiment of the present invention, there is no discrete write driver; rather, the sense amplifier is used as both a sense amplifier (during read operations) and a write driver (during write operations).

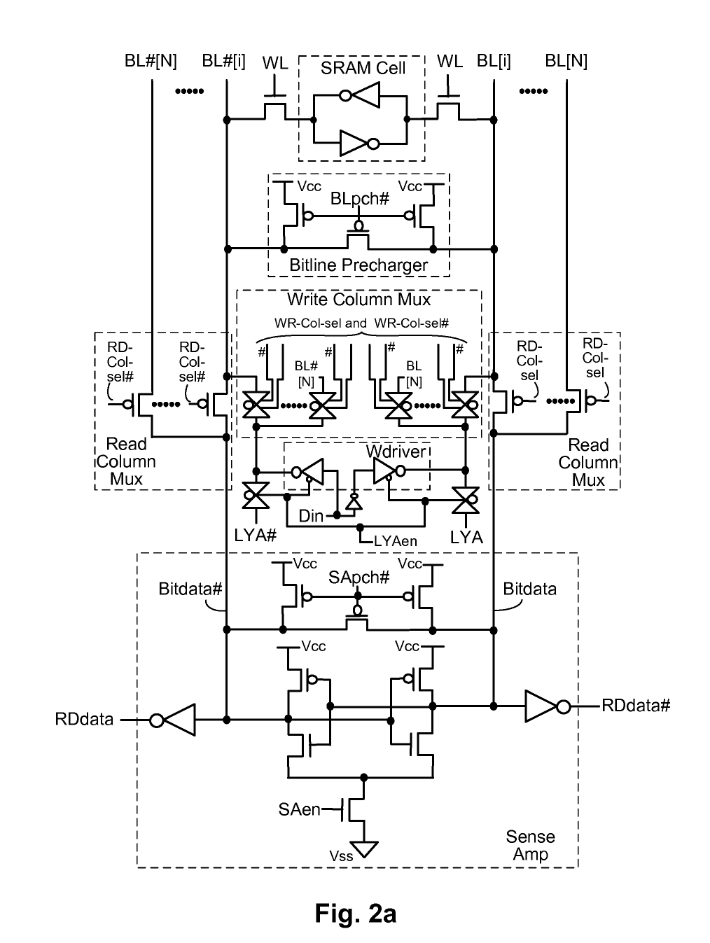

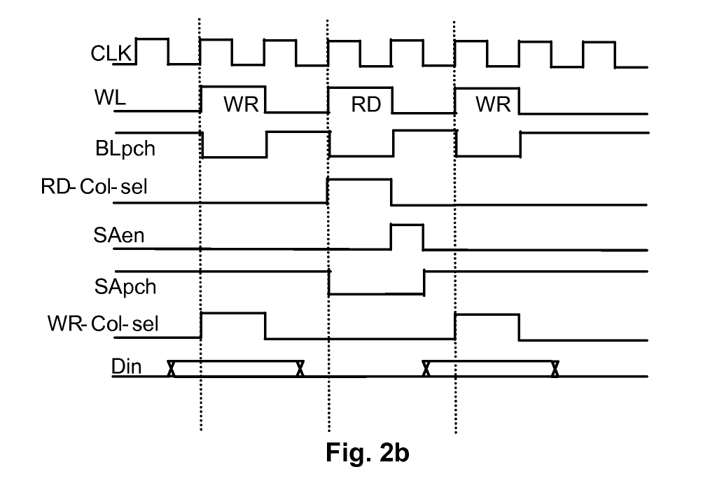

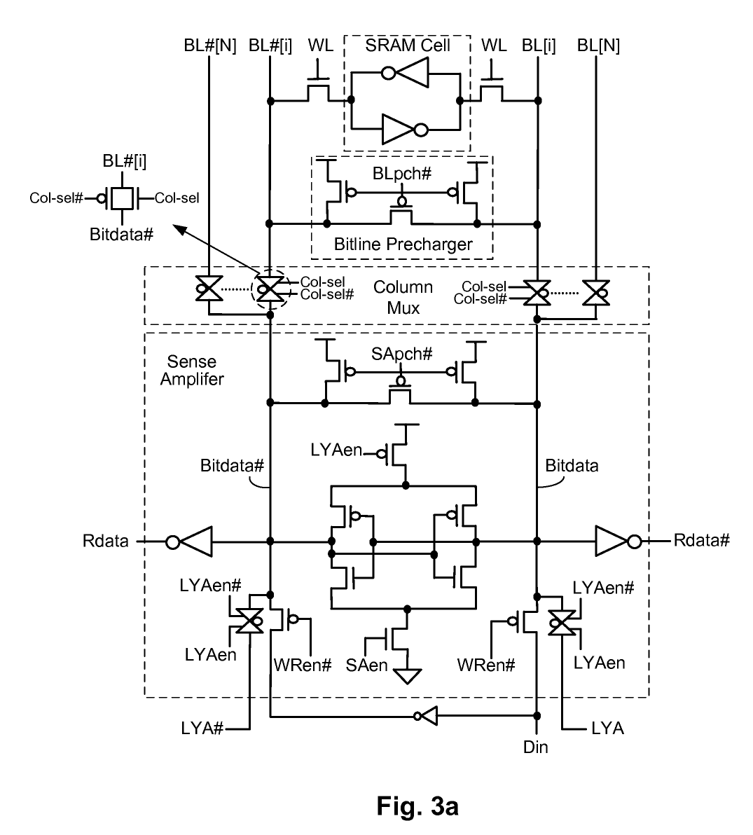

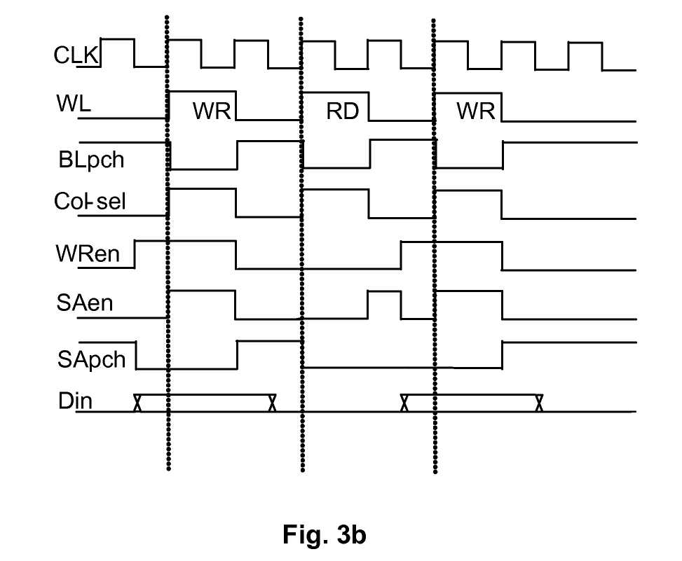

Additional details with respect to the column muxes, bitline prechargers, and sense amplifiers will be provided with reference to FIGS. 2a-2b and 3a-3b. Numerous configurations for I/O circuitry can be used with an embodiment of the present invention, as will be appreciated in light of this disclosure.

Separate Sense Amp and Write Driver

FIG. 2a is a schematic diagram showing an example memory array having I/O circuitry configured with a sense amplifier (Sense Amp) for read operations, a write driver (Wdriver) for write operations, and separate column muxes for read and write operations (Read Column Mux and Write Column Mux, respectively). In this particular example, one slice of a sub-array is shown, but the other slices or portions of the sub-array (or overall array) can be similarly coupled, as will be appreciated.

For purposes of this discussion, assume, for example, that i=0 and N=7, for a total of eight columns per slice. Further, note that only one SRAM cell of column 0 is shown, but memory array columns are typically associated with multiple SRAM cells, as will be appreciated. As can be seen, the SRAM cells of column 0 and its bitline precharging circuit are connected to the corresponding true bitline BL[0] and complementary bitline BL#[0] Likewise, each of the SRAM cells of columns 1-7 and their respective bitline precharging circuits are similarly connected to the corresponding true bitlines BL[1] to BL[7] and complementary bitline BL#[1] to BL#[7], respectively. Columns are then multiplexed in order (e.g., from 0 to 7, or other suitable sequence) to a sense amplifier (for reading operations) or a write driver (for writing operations).

The read column mux in this example case is implemented with PMOS FETs (two for each column, for true and complement bitlines), which is common for Vcc precharged bitline configurations. Each PMOS FET of the read column mux is responsive to the RD-Col-sel control signal (or its complement in this example case, RD-Col-sel#, which works well with PMOS), which is generated by the decoder. When turned on by RD-Col-sel#, the corresponding PMOS FET of the read column mux connects the selected bitline to the sense amplifier associated with that column. For example, when column 0 is selected, the differential bitlines BL[0]/BL#[0] are connected to the differential bitline input Bitdata and Bitdata# of the sense amplifier. The sense amplifier precharge circuit, which in this example case are implemented with PMOS FETs and controlled by the SApch# control signal, are connected to Bitdata and Bitdata# to precharge the sense amplifier bitline input before the sensing. The sense amplifier driver circuit then sends the read data out through RDdata/RDdata#.

As can be further seen with reference to FIG. 2a, the bitlines are also connected to a write driver and low yield analysis (LYA) circuits through the write column mux. The write column mux is in this example embodiment is implemented with complementary metal oxide semiconductor (CMOS) transmission gates, each of which is responsive to the control signal WR-Col-sel and its complement WR-Col-sel#. When turned on by the differential control signal WR-Col-sel, the corresponding CMOS transmission gates of the write column mux connects the selected bitline to the write driver associated with that column. For example, when column 0 is selected, the differential bitlines BL[0]/BL#[0] are connected to the differential output of the write driver, so that data Din (logic 1 or 0) can be converted to a differential signal by the write driver and driven onto differential bitlines BL[0]/BL#[0] and ultimately written to the selected SRAM cell.

The LYA feature is used to connect to the SRAM cells through external LYA pads, for purposes of testing/analysis of the memory array. When LYA is enabled (LYAen is logic 1 and LYAen# is logic 0), a write instruction is issued to open the write column mux (via WR-Col-sel) and the LYAen differential control signal effectively disables the write driver (e.g., by placing the write drive in tri-state mode). Note that LYAen is a differential signal, but only LYAen is shown.

FIG. 2b shows the signal timing of the example memory array of FIG. 2a during Write-Read-Write case. As can be seen, the memory array of this example is a two-cycle memory, in that each read or write operation takes two cycles of the clock (CLK). Other clocking schemes can be used as well.

As can further be seen, the sub-array bitline precharger as well as the precharge transistors of the sense amplifier are on during non access periods, as evidenced by the BLpch and SApch control signals being logic high prior to the initial write operation. When a write operation commences, the data to be written (Din) generally appears before the word line (WL) cycle. The bitline precharge (BLpch) control signal is turned off right before the WL control signal is turned on and the write column select (WR-Col-sel) control signal is turned on. When the data Din is written to the selected bitcell, the wordline WL and WR-Col-sel control signals are turned off, and the BLpch control signal is turned back on to precharge the bitline for the next access.

Similarly, when a read is issued, the BLpch and SApch control signals re turned off, and the WL control signal is turned ON to start the sensing and to develop the differential voltage at the bit lines. Since the RD-Col-sel control signal is also turned on and the SApch control signal is turned off, the resulting differential signal on the bitlines is transferred to sense amplifier in the same WL-on cycle. Once the differential at the sense amplifier bitline input is enough to compensate the sense amplifier offset, the sense amplifier is enabled (SAen=logic 1) and the data read from the selected bitcell is sent out. Once the data is sensed at the sense amplifier, the RD-Col-sel control signal can be turned off and the BLpch control signal is turned on to start the bitline precharge for the next instruction. Once the data is sent out, the sense amplifier can be turned off (SAen=logic 0) to start the sense amplifier precharge (SApch=logic 1).

Thus, in a typical SRAM array, every bitline has both read and write column muxes and precharge circuitry. The write driver, sense amplifier, and LYA circuitry are shared by several columns (typically 4, 8, or 16 columns participate in the sharing). However, neither the read and write column muxes nor the write driver and sense amplifier are used simultaneously. An embodiment of the present invention exploits this observation, to use the sense amplifier as a write driver and to share a mux for both read and write operations (as opposed to having separate read and write muxes).

Sense Amp as Write Driver

FIG. 3a is a schematic diagram showing an example memory array having I/O circuitry configured with a sense amplifier for sensing during read operations and for writing during write operations, and a column mux for both read and write operations. In this particular example, one slice of a sub-array is shown, but the other slices or portions of the sub-array (or overall array) can be similarly coupled, as will be appreciated. Note that the sub-array is configured with differential circuitry as commonly done. Other embodiments may be implemented with single ended circuitry.

For purposes of this discussion, assume, for example, that i=0 and N=7, for a total of eight columns per slice. Further, note that only one SRAM cell of column 0 is shown, but memory array columns are typically associated with multiple SRAM cells, as will be appreciated. As can be seen, the SRAM cells of column 0 and its bitline precharging circuit are connected to the corresponding true bitline BL[0] and complementary bitline BL#[0] Likewise, each of the SRAM cells of columns 1-7 and their respective bitline precharging circuits are similarly connected to the corresponding true bitlines BL[1] to BL[7] and complementary bitline BL#[1] to BL#[7], respectively. Columns are then multiplexed in order (e.g., from 0 to 7, or other suitable sequence) to a sense amplifier, which is used for both reading and writing operations.

The column mux in this example case is implemented with CMOS transmission gates (two for each column, for true and complement bitlines). Each CMOS transmission gate of the column mux is responsive to the Col-sel control signal (and its complement in this example case, Col-sel#, as CMOS uses both the true and complement signals), which is generated by the decoder. FIG. 3a illustrates two common depictions of a CMOS transmission gate, one including two inward facing triangles with a bubble (as indicated in the dashed circle) and the other having an NMOS FET facing a PMOS FET with their respective source and drains connected together (as indicated by the arrow coming off the dashed circle). The column mux may be implemented with other suitable configurations (e.g., differential single-ended) and technology (e.g., NMOS or PMOS transistors), as will be appreciated in light of this disclosure, and the claimed invention is not intended to be limited to any particular configuration or process type. In general, any multiplexer circuit capable of switching in one of many bitlines, in response to a control signal (Col-sel), to the sense amplifier for both read and write operations can be used.

When turned on by Col-sel#, the corresponding CMOS transmission gate of the column mux connects the selected bitline to the sense amplifier associated with that column. For example, when column 0 is selected, the differential bitlines BL[0]/BL#[0] are connected to the differential bitline input Bitdata and Bitdata# of the sense amplifier. The sense amplifier precharge transistors, which in this example case are implemented with PMOS FETs and controlled by the SApch# control signal, are connected to Bitdata and Bitdata# to precharge the sense amplifier bitline input before the sensing. The sense amplifier driver then sends the read data out through RDdata/RDdata#.

As can be further seen with reference to FIG. 3a, the sense amplifier is further configured to carry out the function of write driver. In more detail, during a write operation, the write enable control signal WRen# is set to logic 0, thereby indicating a write access has been requested. This WRen# control signal can be provided, for example, directly by the decoder or derived from existing signals that indicate a write access request. The WRen# control signal controls two PMOS FETs (one for the true bitline, and one for the complement bitline), which when turned on, couple the differential data input to the sense amplifier bitline inputs, Bitdata and Bitdata#. This in turn allows the differential required to compensate the sense amplifier offset to develop. The differential data input of the write operation is Din and its complement, which is generated by an inverter in this example configuration. Any suitable circuitry for converting the data input to a differential signal can be used here. Thus, the addition of the PMOS FETs and WRen# control signal allow the sense amplifier to be used in a write mode (WRen#=0) or a read mode (WRen#=1).

A number of variations on this multimode sense amplifier configuration will be apparent in light of this disclosure. For instance, in another embodiment, the sense amplifier can be configured with NMOS FETs that are responsive to the true version of the write enable control signal, WRen (as opposed to its complement, WRen#). In such cases, when WRen is set to logic 1 to indicate a write access has been requested, the NMOS FETs will turn on and couple the differential data input (Din and its complement) to the sense amplifier bitline input, Bitdata and Bitdata#. Other embodiments may include CMOS transmission gates for switching the sense amplifier from read mode to write mode. In a more general sense, any suitable switching element or scheme can be used to couple the differential data input to the sense amplifier bitline input during a write operation.

In any such cases, the column mux receives the data to be written from the differential lines Bitdata and Bitdata#, and the corresponding CMOS transmission gates of the column mux connects the selected bitline to the differential lines Bitdata and Bitdata#, so that the differential data thereon can be written to and stored in the target SRAM cell. For example, when column 0 is selected by virtue of the Col-sel/Col-sel# signal (provided by the decoder), the differential bitlines BL[0]/BL#[0] are connected to the differential lines Bitdata and Bitdata#, so that data Din (logic 1 or 0) thereon can be driven onto differential bitlines BL[0]/BL#[0] and stored in the selected SRAM cell.

This example embodiment also includes optional LYA circuitry, which is implemented with CMOS muxes controlled by the differential control signal LYAen/LYAen#. The LYA muxes are connected to the differential lines Bitdata and Bitdata#, and depending on the state of LYAen/LYAen#, couple the LYA and LYA# inputs to the differential lines Bitdata and Bitdata#. As previously explained, the LYA feature is used to connect to the SRAM cells through external LYA pads, for purposes of testing/analysis of the memory array. When LYA is enabled (LYAen is logic 1 and LYAen# is logic 0), a write instruction is issued to open the column mux (via Col-sel) so the target SRAM cell can be accessed. Any number of LYA testing/analysis schemes can be employed.

FIG. 3b shows the signal timing of the example memory array of FIG. 3a during Write-Read-Write case. In this example, the memory array is a two-cycle memory, in that each read or write operation takes two cycles of the clock (CLK). However, other embodiments may be, for example, a one-cycle memory, three-cycle memory, etc. Any number of suitable clocking schemes can be used. Also, note that although differential signals can be used (depending on, for example, the componentry used, such as PMOS, NMOS, CMOS and the desired active states), only the true signals are shown. Use of complementary signals will be apparent in light of this disclosure.

As can be seen, the sub-array bitline precharger as well as the precharge transistors of the sense amplifier are assumed to be on during non access periods, as evidenced by the BLpch and SApch control signals being logic high prior to the initial write operation. Note, however, that other embodiments could use a bitline floating scheme or otherwise limit the bitline precharging until a cycle or two prior to access so as to reduce leakage and/or power consumption.

When a Write is issued, data Din appears before the word line (WL) cycle. The write enable (WRen) control signal is enabled (WRen=1) and SApch control signal is disabled (SApch#=1) to transfer the data to the sense amplifier bitline input (Bitdata and Bitdata#). Then, the bitline precharge (BLpch) control signal is turned off (BLpch#=1) right before the WL control signal is turned on, the sense amplifier is enabled (SAen=1) and the column select control signal is turned on (Col-sel=1). During this WL-cycle, the sense amplifier writes the data to the selected SRAM bitcell. When the data is written to selected bitcell, the WL and Col-sel control signals are turned off, thereby turning off the corresponding WL transistor (e.g., NMOS transistor in FIG. 3a) and Col-sel multiplexer (e.g., CMOS transmission gate in FIG. 3a). At the same time, the WRen and SAen control signals are turned off (to exit the sense amplifier write mode and disable the sense amplifier), and the BLpch control signal is enabled to precharge the BL[i] and BL#[i] for the next access.

Similarly, when a read is issued, the BLpch control signal is turned off and WL control signal is turned ON to start the sensing, and to develop the differential voltage at the bitlines. Since the Col-sel control signal is also turned on and the SApch control signal is turned off, the differential will be transferred to the sense amplifier bitline input (Bitdata and Bitdata#) in the same WL-on cycle. Once the sense amplifier differential is enough to compensate the sense amplifier offset, the sense amplifier is enabled (SAen=1) and the data is sent out (e.g., on RDdata# for a single-ended output, or on both RDdata and RDdata# for a differential output). Once the data is sensed at the sense amplifier, the Col-sel control signal can be turned off to start the bitline precharge for the next instruction (BLpch#=0). Once the data is sent out, the sense amplifier can be turned off to start the sense amplifier precharge (SApch#=0).

By using the sense amplifier of a memory array as a write driver during write operations, and by using the same column mux for both read and write operation, a significant memory array area reduction is achieved. For instance, the area savings, as a result of eliminating the write driver and sharing the column mux in accordance with one embodiment of the present invention, is about 3%-4% at the sub-array level, and 1%-2% at the die level, depending on the memory configuration.

System

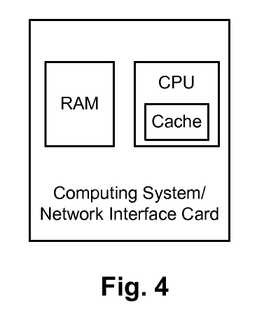

FIG. 4 illustrates a system having one or more memory arrays configured in accordance with an embodiment of the present invention. The system can be, for example, a computing system (e.g., laptop or desktop computer, server, or smart phone) or a network interface card or any other system that employs memory. As will be appreciated, memory technology effectively has an almost unlimited number of applications at the system level, and the specific system shown is merely provided as an example.

As can be seen, the system generally includes a RAM and central processing unit (CPU, or processor) configured with on-chip cache. Any suitable processor can be used, such as those provided by Intel Corporation (e.g., Intel® Core™, Pentium®, Celeron®, and Atom™ processor families). The processor can access its on-chip cache and/or the RAM and execute functionality particular to a given application, as commonly done. Each of the RAM and/or on-chip cache can be implemented as a memory array having a sense amplifier capable of operating in both read and write modes and using a common column mux for both read and write operations, as described herein. Other system componentry (such as display, keypad, random access memory, co-processors, bus structures, etc) are not shown, but will be apparent given the particular system application at hand.

Numerous embodiments and configurations will be apparent in light of this disclosure. For instance, one example embodiment of the present invention provides a memory device. The memory device includes a memory array having a plurality of memory cells, each for storing a bit of information. The memory device further includes a sense amplifier configured to operate in a reading mode for readout of memory cells and a writing mode for writing to memory cells. In one particular case, the device may further include a bitline precharging circuit for precharging a bitline associated with a column of the memory array, and/or a circuit (e.g., timer) for generating a precharge control signal that enables the bitline precharging circuit to precharge the bitline. In another particular case, the device may include a decoder for receiving an address associated with a read or write access of the memory array, and generating a word line signal for selecting a corresponding row of the memory array, and generating a column select line for selecting a corresponding column of the memory array. In another particular case, the device may include a column multiplexer for allowing multiple columns of the memory array to share the sense amplifier for readout of memory cells in those columns and for writing to memory cells in those columns. In another particular case, the sense amplifier is configured with a data input for receiving data to be written to one or more of the memory cells, the sense amplifier further configured with one or more switching elements for coupling the data to a bitline input of the sense amplifier during a write operation. In one such particular case, the device further includes circuitry for converting the data to a differential signal, and passing that differential signal to the one or more switching elements. In another particular case, the sense amplifier is configured to receive a write enable control signal that allows the sense amplifier to enter the writing mode. In another particular case, the device is a static random access memory (SRAM). In another particular case, the device may include low yield analysis circuitry.

Another example embodiment of the present disclosure provides a memory device. In this example, the device includes a memory array having a plurality of memory cells, each for storing a bit of information. The device further includes a sense amplifier configured to operate in a reading mode for readout of memory cells and a writing mode for writing to memory cells, wherein the sense amplifier is configured with a data input for receiving data to be written to one or more of the memory cells, the sense amplifier further configured with one or more switching elements for coupling the data to a bitline input of the sense amplifier during a write operation. The device further includes a column multiplexer for allowing multiple columns of the memory array to share the sense amplifier for readout of memory cells in those columns and for writing to memory cells in those columns. In one particular case, the device may include a bitline precharging circuit for precharging a bitline associated with a column of the memory array, and/or a circuit for generating a precharge control signal that enables the bitline precharging circuit to precharge the bitline. In another particular case, the device may include a decoder for receiving an address associated with a read or write access of the memory array, and generating a word line signal for selecting a corresponding row of the memory array, and generating a column select line for selecting a corresponding column of the memory array. In another particular case, the device may include circuitry for converting the data to a differential signal, and passing that differential signal to the one or more switching elements. In another particular case, the sense amplifier is configured to receive a write enable control signal that allows the sense amplifier to enter the writing mode. In another particular case, the device may include low yield analysis circuitry.

Another example embodiment of the present disclosure provides a method for accessing a memory device having an array of memory cells. The memory includes reading data from one or more memory cells of the array using a sense amplifier operating in a reading mode, and writing data to one or more memory cells of the array using the sense amplifier operating in a writing mode. In one particular case, the method may further include precharging a bitline associated with a column of the array, and/or generating a precharge control signal that enables the bitline precharging circuit to precharge the bitline. In another particular case, the method may include receiving an address associated with a read or write access of the array, generating a word line signal for selecting a corresponding row of the array, and/or generating a column select line for selecting a corresponding column of the array. In another particular case, the method may include allowing multiple columns of the array to share the sense amplifier for readout of memory cells in those columns and for writing to memory cells in those columns. In another particular case, the method may include receiving, at a data input of the sense amplifier, data to be written to one or more of memory cells of the array, and coupling the data to a bitline input of the sense amplifier during a write operation. In one such particular case, the method may include converting the data to a differential signal, and passing that differential signal to one or more switching elements configured for coupling the data to a bitline input of the sense amplifier during a write operation. In another particular case, the method may include receiving, at the sense amplifier, a write enable control signal that allows the sense amplifier to enter the writing mode.

Another example embodiment of the present disclosure provides a memory device. In this example case, the device includes a memory array having a plurality of memory cells. The device further includes a sense amplifier having a precharge circuit operatively coupled to a differential bitline input of the sense amplifier, the sense amplifier further having a driver circuit operatively coupled between the differential bitline input and an output of the sense amplifier, the sense amplifier further having one or more switching elements responsive to a write enable control signal and for coupling data to be written to one or more of the memory cells to the differential bitline input during a write operation. The device further includes a column multiplexer for allowing multiple columns of the memory array to share the sense amplifier for readout of memory cells in those columns and for writing to memory cells in those columns. The device further includes a bitline precharging circuit. The device further includes a circuit for generating a precharge control signal that enables the bitline precharging circuit. The device further includes a decoder.

The foregoing description of example embodiments of the invention has been presented for the purposes of illustration and description. It is not intended to be exhaustive or to limit the invention to the precise forms disclosed. Many modifications and variations are possible in light of this disclosure. It is intended that the scope of the invention be limited not by this detailed description, but rather by the claims appended hereto.

What is claimed is:

1. A memory device, comprising:
a memory array having a plurality of memory cells, each for storing a bit of information; and
a sense amplifier configured to operate in a reading mode for readout of memory cells and a writing mode for writing to memory cells.

2. The device of claim 1 comprising at least one of:
a bitline precharging circuit for precharging a bitline associated with a column of the memory array; and
a circuit for generating a precharge control signal that enables the bitline precharging circuit to precharge the bitline.

3. The memory device of claim 1 further comprising:
a decoder for receiving an address associated with a read or write access of the memory array, and generating a word line signal for selecting a corresponding row of the memory array, and generating a column select line for selecting a corresponding column of the memory array.

4. The memory device of claim 1 further comprising:
a column multiplexer for allowing multiple columns of the memory array to share the sense amplifier for readout of memory cells in those columns and for writing to memory cells in those columns.

5. The memory device of claim 1 wherein the sense amplifier is configured with a data input for receiving data to be written to one or more of the memory cells, the sense amplifier further configured with one or more switching elements for coupling the data to a bitline input of the sense amplifier during a write operation.

6. The memory device of claim 5 further comprising circuitry for converting the data to a differential signal, and passing that differential signal to the one or more switching elements.

7. The memory device of claim 1 wherein the sense amplifier is configured to receive a write enable control signal that allows the sense amplifier to enter the writing mode.

8. The memory device of claim 1 wherein the device is a static random access memory (SRAM).

9. The memory device of claim 1 further comprising:
low yield analysis circuitry.

10. A memory device, comprising:
a memory array having a plurality of memory cells, each for storing a bit of information;
a sense amplifier configured to operate in a reading mode for readout of memory cells and a writing mode for writing to memory cells, wherein the sense amplifier is configured with a data input for receiving data to be written to one or more of the memory cells, the sense amplifier further configured with one or more switching elements for coupling the data to a bitline input of the sense amplifier during a write operation; and
a column multiplexer for allowing multiple columns of the memory array to share the sense amplifier for readout of memory cells in those columns and for writing to memory cells in those columns.

11. The device of claim 10 comprising at least one of:
a bitline precharging circuit for precharging a bitline associated with a column of the memory array; and
a circuit for generating a precharge control signal that enables the bitline precharging circuit to precharge the bitline.

12. The memory device of claim 10 further comprising:
a decoder for receiving an address associated with a read or write access of the memory array, and generating a word line signal for selecting a corresponding row of the memory array, and generating a column select line for selecting a corresponding column of the memory array.

13. The memory device of claim 10 further comprising circuitry for converting the data to a differential signal, and passing that differential signal to the one or more switching elements.

14. The memory device of claim 10 wherein the sense amplifier is configured to receive a write enable control signal that allows the sense amplifier to enter the writing mode.

15. The memory device of claim 10 further comprising:
low yield analysis circuitry.

16. A method for accessing a memory device having an array of memory cells, the method comprising:
reading data from one or more memory cells of the array using a sense amplifier operating in a reading mode; and
writing data to one or more memory cells of the array using the sense amplifier operating in a writing mode.

17. The method of claim 16 comprising at least one of:
precharging a bitline associated with a column of the array; and
generating a precharge control signal that enables the bitline precharging circuit to precharge the bitline.

18. The method of claim 16 further comprising:
receiving an address associated with a read or write access of the array;
generating a word line signal for selecting a corresponding row of the array; and
generating a column select line for selecting a corresponding column of the array.

19. The method of claim 16 further comprising:
allowing multiple columns of the array to share the sense amplifier for readout of memory cells in those columns and for writing to memory cells in those columns.

20. The method of claim 16 further comprising:
receiving, at a data input of the sense amplifier, data to be written to one or more of memory cells of the array; and
coupling the data to a bitline input of the sense amplifier during a write operation.

21. The method of claim 20 further comprising:
converting the data to a differential signal; and
passing that differential signal to one or more switching elements configured for coupling the data to a bitline input of the sense amplifier during a write operation.

22. The method of claim 16 further comprising:
receiving, at the sense amplifier, a write enable control signal that allows the sense amplifier to enter the writing mode.

23. A memory device, comprising:
a memory array having a plurality of memory cells;
a sense amplifier having a precharge circuit operatively coupled to a differential bitline input of the sense amplifier, the sense amplifier further having a driver circuit operatively coupled between the differential bitline input and an output of the sense amplifier, the sense amplifier further having one or more switching elements responsive to a write enable control signal and for coupling data to be written to one or more of the memory cells to the differential bitline input during a write operation;
a column multiplexer for allowing multiple columns of the memory array to share the sense amplifier for readout of memory cells in those columns and for writing to memory cells in those columns;
a bitline precharging circuit;
a circuit for generating a precharge control signal that enables the bitline precharging circuit; and
a decoder.
